(19) United States
(12) Patent Application Publication
(10) Pub. No.: US 2023/0215788 A1
(43) Pub. Date: Jul. 6, 2023

(54) POWER MODULE AND MANUFACTURING METHOD THEREOF, CONVERTER, AND ELECTRONIC DEVICE

(71) Applicant: HUAWEI TECHNOLOGIES CO., LTD., SHENZHEN (CN)

(72) Inventors: Wengang LUO, Shanghai (CN); Zhaozheng HOU, Dongguan (CN); Junhe WANG, Shanghai (CN)

(21) Appl. No.: 18/183,367

(22) Filed: Mar. 14, 2023

Related U.S. Application Data
(63) Continuation of application No. PCT/CN2020/115360, filed on Sep. 15, 2020.

(51) Int. Cl. H01L 23/495; H01L 23/31; H01L 21/48; H01L 23/498; H01L 25/07

(52) U.S. Cl. CPC H01L 23/49575; H01L 23/49562; H01L 23/3121; H01L 23/49568; H01L 21/4846; H01L 23/49811; H01L 23/49579; H01L 25/072

(57) ABSTRACT

A power module (10) and a manufacturing method thereof are disclosed. The power module (10) includes a power assembly (11) and a drive board (12). The power assembly (11) includes a substrate (111), a power chip (112), and a package body (113). The power chip (112) is disposed on a mounting surface (1110) of the substrate (111). The package body (113) packages the power chip (112) on the substrate (111). The drive board (12) is disposed in the package body (113) and is located on a side, of the power chip (112), that backs the mounting surface (1110). The drive board (12) is electrically connected to the power chip (112). In the power module, a parasitic parameter between the drive board (12) and the power assembly (11) can be reduced, thereby improving electrical performance of the power module (10).

### CROSS-REFERENCE TO RELATED APPLICATIONS

This application is a continuation of International Application No. PCT/CN2020/115360, filed on Sep. 15, 2020, the disclosure of which is hereby incorporated by reference in its entirety.

### TECHNICAL FIELD

This application relates to the field of chip packaging technologies, and in particular, to a power module and a manufacturing method thereof, a converter, and an electronic device.

### BACKGROUND

A power module is a module obtained by combining and packaging electronic power devices based on specific functions. In the conventional technology, a power module is connected to a drive board, and a switch of a power chip packaged in the power module is controlled by using the drive board. However, in the conventional technology, a parasitic parameter between the drive board and the power chip in the power module is excessively large, affecting electrical performance of the power module.

### SUMMARY

Embodiments of this application protect a power module, to reduce a parasitic parameter between a drive board and the power module, and improve electrical performance of the power module.

Embodiments of this application further protect a manufacturing method for a power module, a converter including the power module, and an electronic device including the converter.

According to an aspect, this application protects a power module. The power module includes a power assembly and a drive board. The power assembly includes a substrate, a power chip, and a package body. The power chip is disposed on a mounting surface of the substrate. The package body packages the power chip on the substrate. The drive board is disposed in the package body and is located on a side, of the power chip, that backs the mounting surface. The drive board is electrically connected to the power chip.

In the power module in this embodiment, the drive board is disposed in the package body of the power assembly, and the drive board is located on the side, of the power chip, that backs the mounting surface, to reduce a distance between the drive board and the power chip. Further, a connection line between the power chip and the drive board is shortened, thereby effectively reducing a parasitic parameter of the connection line between the power chip and the drive board, that is, reducing a parasitic parameter of the power module, and improving electrical performance of the power module. In addition, the drive board is disposed in the package body of the power assembly, that is, the drive board is disposed inside the power assembly. Compared with disposing the drive board and the power assembly on a same plane, this can effectively reduce a planar area of the power module. When the package body is formed for the power assembly, to ensure strength of the power assembly, a thickness of the power assembly is usually greater than 5 mm. This thickness is sufficient to allow the drive board to be embedded in the package body of the power assembly, without increasing the thickness of the power assembly. That is, disposing the drive board in the package body does not affect the thickness of the power assembly, thereby effectively improving integration of the power module, reducing a package size, and reducing costs of the power module.

It may be understood that there are mainly two parasitic parameters: a parasitic inductance and a parasitic resistance. A magnitude of the parasitic inductance is mainly affected by two factors: a length of the connection line, where a longer connection line results in a larger parasitic inductance; and an area surrounded by the connection line, where a larger area surrounded by the connection line results in a larger parasitic inductance. For the parasitic resistance, a longer connection line results in a larger parasitic resistance. Therefore, in this application, a shorter distance between the drive board and the power chip indicates a shorter connection line between the drive board and the power chip, and an area surrounded by the connection line is also reduced, thereby effectively reducing a parasitic inductance and a parasitic resistance of the power module, and improving electrical performance of the power module.

In some embodiments, in a direction perpendicular to the mounting surface, a distance between the drive board and the power chip is less than a distance between the drive board and a surface, of the package body, that backs the mounting surface. In this embodiment, the distance between the drive board and the power chip is required to be less than the distance between the drive board and the surface, of the package body, that backs the mounting surface, to ensure that the distance between the drive board and the power chip is sufficiently short, thereby ensuring that the parasitic parameter of the connection line between the drive board and the power chip is sufficiently small, and effectively improving electrical performance of the power module.

In some embodiments, the power assembly further includes a pin. The pin penetrates the drive board and a part of the package body. One end of the pin is disposed on the mounting surface and is electrically connected to the power chip, and the other end of the pin is exposed from the package body. The pin is configured to implement an electrical connection between the power chip and a circuit board. Certainly, in another embodiment, the pin of the power chip may be alternatively configured to implement an electrical connection between the power chip and the drive board. Alternatively, the pin may not penetrate the drive board. Alternatively, the power chip may be connected to the circuit board by using a structure other than the pin.

In some embodiments, the drive board is electrically connected to the power chip through the pin. To be specific, the pin is electrically connected to the drive board, so that the drive board is electrically connected to the power chip. The pin can implement an electrical connection between the power chip and a drive chip on the drive board, and can also implement an electrical connection between the power chip and the external circuit board, thereby simplifying a structure of the power module.

In some embodiments, the power module further includes a conductor. The conductor is located between the power chip and the drive board. The power chip is connected to the drive board through the conductor. Because the drive board is disposed in the package body of the power assembly, the distance between the drive board and the power chip is reduced. Further, the connection line (the conductor) connected between the drive board and the power chip is shortened, thereby effectively reducing the parasitic parameter of the connection line of the power module, and improving electrical performance of the power module.

In some embodiments, the conductor is a copper rod, and two ends of the copper rod are respectively electrically connected to the power chip and the drive board. A length of the copper rod is equal to the distance between the drive board and the power chip. It may be understood that a length direction of the copper rod is a flow direction of a current in the copper rod, so that the length of the copper rod is the shortest, thereby effectively reducing the parasitic parameter of the connection line of the power module, and improving electrical performance of the power module.

In some embodiments, the conductor is a lead frame. The lead frame includes a first terminal and a second terminal that are connected to each other. The first terminal is electrically connected to the power chip. The second terminal is electrically connected to the drive board. In this implementation, the lead frame has a quite good through-current capability, thereby effectively reducing the parasitic parameter of the power module, and effectively improving a heat dissipation capability of the power chip. In addition, two power chips may also be electrically connected through the lead frame, thereby effectively reducing manufacturing steps of the power module, and improving production efficiency of the power module.

In some embodiments, the lead frame further includes a third terminal electrically connected to the first terminal, and the third terminal is electrically connected to the pin. To be specific, the lead frame can also implement an electrical connection between the pin and the power chip, so that no additional lead needs to be introduced to connect the power chip and the pin. Therefore, a structure of the power module is simpler, and manufacturing steps of the power module are reduced, thereby improving production efficiency of the power module. In addition, compared with a lead, the lead frame has a stronger through-current capability and a smaller parasitic parameter, so that heat dissipation effect of the power chip can be further improved.

In some embodiments, the package body is formed by using a plastic packaging process. The package body formed by using the plastic packaging process has good sealing performance, so that moisture resistance and reliability of a packaged structure can be improved.

In some embodiments, the power module further includes a package housing. The power assembly and the drive board are accommodated in the package housing. An end, of the pin, that backs the power chip extends out of the package housing. The package body is injected into a gap in the package housing by using a housing packaging process. In this application, the package body is formed by using the housing packaging process. The process is simple, thereby effectively improving production efficiency of the power module.

In some embodiments, the drive board and the power assembly constitute a packaged structure. A surface, of the substrate, that backs the power chip is a rear surface. The rear surface is exposed from the package body. The power module further includes a heat sink. The heat sink is fastened to the packaged structure and is in contact with the rear surface. The rear surface of the substrate is in direct contact with the heat sink, so that heat of the power chip can be quickly transmitted to the heat sink and then transmitted by the heat sink to the outside, thereby effectively improving heat dissipation efficiency of the power chip.

In some embodiments, the drive board includes a center region and an edge region surrounding the center region. The center region is arranged opposite to the power assembly. The packaged structure includes a mounting hole. The mounting hole is located in the edge region, and penetrates the drive board and the package body in a direction from the drive board to the power chip. The heat sink is connected to the packaged structure through the mounting hole. The edge region and the package body located in the edge region may be understood as a mounting part of the packaged structure, so that the packaged structure is fastened to another component by using the mounting part.

In some embodiments, a surface, of the edge region, that backs the power chip is exposed from the package body, so that a screw is fastened through the surface, of the edge region, that backs the power chip. The package body is made of a brittle material, and the package body is prone to breakage under large stress. Because no package body is disposed in the edge region, the screw directly transmits a locking force to the drive board, thereby reducing stress applied to the package body, and avoiding a risk that the package body cracks because the screw directly transmits the locking force to the package body.

In some embodiments, there are two power assemblies. Mounting surfaces of the two power assemblies are arranged opposite to each other and are electrically connected to each other. Package bodies of the two power assemblies are connected. The drive board is disposed between the two power assemblies and is electrically connected to at least one power assembly. In this embodiment, the drive board is embedded between the two power assemblies, to shorten distances between the drive board and power chips of the two power assemblies, and further shorten connection lines between the drive board and the power chips of the two power assemblies, thereby effectively reducing parasitic parameters of the connection lines, and improving electrical performance of the power module.

According to a second aspect, this application protects a converter. The converter includes a circuit board and the power module according to any one of the foregoing embodiments. The power module is electrically connected to the circuit board. Integration and electrical performance of the converter with the power module provided in this application are effectively improved.

According to a third aspect, this application protects an electronic device. The electronic device includes the foregoing converter, and the converter is configured to convert an electrical signal of the electronic device. Integration and electrical performance of the electronic device with the converter provided in this application are effectively improved.

According to a fourth aspect, this application protects a manufacturing method for a power module. The manufacturing method includes:
providing a first power board, where the first power board includes a substrate and a power chip disposed on a mounting surface of the substrate;
providing a drive board, disposing the drive board on a side, of the power chip, that backs the mounting surface, and electrically connecting the drive board to the power chip, to form a to-be-packaged structure; and
packaging the to-be-packaged structure by using a package body, to form a power module.

In the manufacturing method for a power module in this application, the drive board is disposed on the side, of the power chip, that backs the mounting surface, the drive board is electrically connected to the power chip to form the to-be-packaged structure, and then the to-be-packaged structure is packaged to form a packaged structure. To be specific, the drive board and the power chip are packaged together, so that a distance between the drive board and the power chip can be shortened. Further, a connection line between the power chip and the drive board is shortened, thereby effectively reducing a parasitic parameter of the connection line between the power chip and the drive board, that is, reducing a parasitic parameter of the power module, and improving electrical performance of the power module. In addition, the drive board and the first power board are packaged together. Compared with disposing the drive board and the first power board on a same plane, this can effectively reduce a planar area of the power module. During packaging of the first power board, to ensure strength of the first power board after packaging, a thickness of the first power board after packaging is usually greater than 5 mm. This thickness is sufficient to allow the drive board and the first power board to be packaged together without increasing the thickness of the first power board. That is, packaging the drive board and the first power board together does not affect the thickness obtained after packaging, thereby effectively improving integration of the power module, reducing a package size, and reducing costs of the power module.

In some embodiments, the manufacturing method further includes: before the disposing the drive board on a side, of the power chip, that backs the mounting surface, forming, on a surface, of the power chip, that backs the mounting surface, a conductor electrically connected to the power chip, where when the drive board is disposed on the side, of the power chip, that backs the mounting surface, the drive board is electrically connected to the conductor. The conductor is configured to connect the power chip to the drive board in a subsequent process, to reduce the parasitic parameter of the power module, and improve electrical performance of the power module.

In some embodiments, the conductor is a copper rod, or the conductor is a lead frame. A length of the copper rod is equal to the distance between the drive board and the power chip. It may be understood that a length direction of the copper rod is a flow direction of a current in the copper rod, so that the length of the copper rod is the shortest, that is, the connection line between the drive board and the power chip is the shortest, thereby effectively reducing the parasitic parameter of the connection line of the power module, and improving electrical performance of the power module. When the conductor is a lead frame, the lead frame implements both an electrical connection between a pin and the power chip and an electrical connection between two power chips, so that no additional lead needs to be introduced to connect the power chip and the pin and connect the two power chips. Therefore, a structure of the power module is simpler, and manufacturing steps of the power module are reduced, thereby improving production efficiency of the power module. In addition, compared with a lead, the lead frame has a stronger through-current capability and a smaller parasitic parameter, so that heat dissipation effect of the power chip can be further improved.

In some embodiments, the manufacturing method further includes: when the power chip is disposed on the mounting surface of the substrate, fastening a pin to the mounting surface, where when the drive board is disposed on the side, of the power chip, that backs the mounting surface, the pin penetrates the drive board. This helps reduce manufacturing steps of the power module, reduce production costs, and improve production efficiency of the power module.

In some embodiments, the manufacturing method further includes: after the drive board is electrically connected to the first power board, providing a second power board, disposing the second power board on a side, of the drive board, that backs the first power board, and electrically connecting the second power board to the first power board, to form a to-be-packaged structure. In this embodiment, the drive board is embedded between the two power boards, to shorten distances between the drive board and power chips of the two power boards, and further shorten connection lines between the drive board and the power chips of the two power boards, thereby effectively reducing parasitic parameters of the connection lines, and improving electrical performance of the power module.

In some embodiments, the to-be-packaged structure is packaged by using a plastic packaging process. In this embodiment, the power module formed by using the plastic packaging process has good sealing performance, so that moisture resistance and reliability of the power module can be improved.

In some embodiments, a specific method for packaging the to-be-packaged structure is as follows: providing a package housing, and fastening the to-be-packaged structure in the package housing; and injecting adhesive into the package housing to fill a gap in the package housing. In this embodiment, the package body is formed by using a housing packaging process. The process is simple, thereby effectively improving production efficiency of the power module.

In some embodiments, the package body and the to-be-packaged structure constitute a packaged structure, a surface, of the substrate, that backs the power chip is a rear surface, and the manufacturing method further includes: providing a heat sink, fastening the heat sink to the packaged structure, and making the heat sink in contact with the rear surface, to improve heat dissipation efficiency of the power chip.

In some embodiments, the drive board includes a center region and an edge region surrounding the center region, the center region is arranged opposite to the power assembly, the edge region includes a via, and the manufacturing method further includes: during packaging of the to-be-packaged structure, forming a mounting hole that penetrates the via and the package body. A specific step of fastening the heat sink to the packaged structure is as follows: A screw passes through the mounting hole and is tightened to the heat sink. Certainly, in another embodiment, the heat sink may be alternatively fastened to the packaged structure by using a screw or in another fastening manner. Alternatively, the packaged structure may be alternatively fastened to the heat sink in another connection manner such as bonding or clamping.

In the power module in this embodiment, the drive board is disposed in the package body of the power assembly, and the drive board is located on the side, of the power chip, that backs the mounting surface, to reduce a distance between the drive board and the power chip. Further, a connection line between the power chip and the drive board is shortened, thereby effectively reducing a parasitic parameter of the connection line between the power chip and the drive board, that is, reducing a parasitic parameter of the power module, and improving electrical performance of the power module.

### BRIEF DESCRIPTION OF DRAWINGS

FIG. 1 is a schematic diagram of a structure of an electronic device according to an embodiment of this application;

FIG. 2 is a schematic diagram of a partial structure of a converter of the electronic device shown in FIG. 1;

FIG. 3 is a schematic diagram of a structure of a first embodiment of a power module of the converter shown in FIG. 2;

FIG. 4 is a schematic diagram of a structure of another embodiment of the power module shown in FIG. 3;

FIG. 5 is a schematic diagram of a structure of a second embodiment of the power module shown in FIG. 2;

FIG. 6 is a schematic diagram of a structure of a third embodiment of the power module shown in FIG. 2;

FIG. 7 is a schematic diagram of a structure of a fourth embodiment of the power module shown in FIG. 2;

FIG. 8 is a schematic flowchart of a manufacturing method for the power module shown in FIG. 3 according to an embodiment; and

FIG. 9 to FIG. 21 are specific schematic diagrams corresponding to the manufacturing method shown in FIG. 8 according to some embodiments.

### DESCRIPTION OF EMBODIMENTS

The following describes embodiments of this application with reference to accompanying drawings in embodiments of this application.

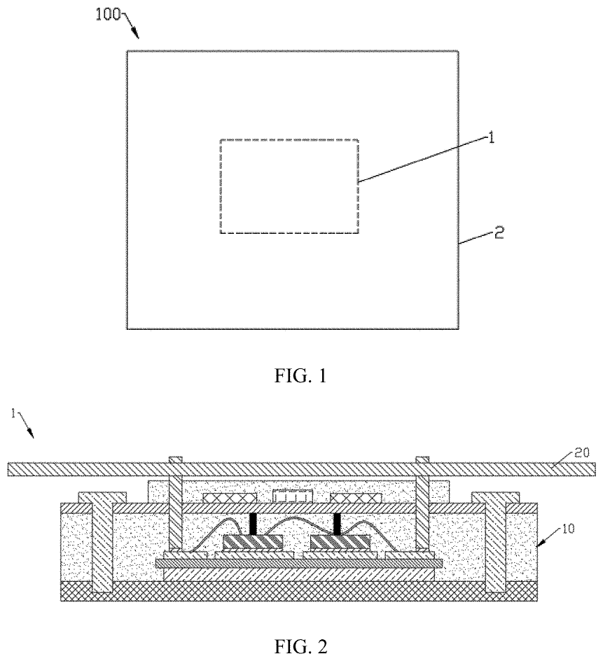

FIG. 1 is a schematic diagram of a structure of an electronic device 100 according to an embodiment of this application.

The electronic device 100 includes a converter 1 and a housing 2. The converter 1 is accommodated in the housing 2, and the converter 1 is configured to convert an electrical signal of the electronic device 100. The electronic device 100 in this embodiment includes but is not limited to an electronic device 100 with the converter 1, such as a wind turbine, a photovoltaic generator, an electric vehicle, and a major appliance. Integration and electrical performance of the electronic device 100 with the converter 1 provided in this application are effectively improved.

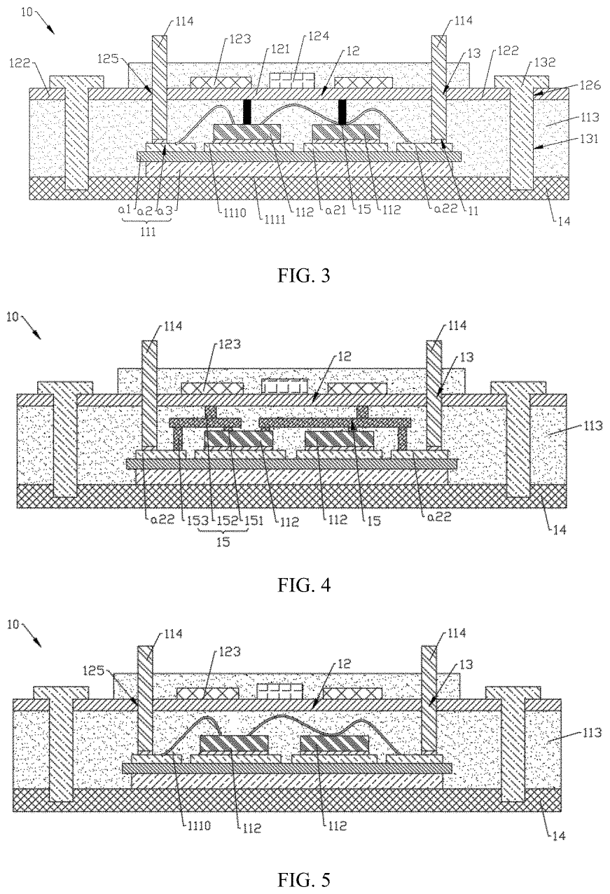

FIG. 2 is a schematic diagram of a partial structure of the converter 1 of the electronic device 100 shown in FIG. 1.

The converter 1 includes a power module 10 and a circuit board 20. The power module 10 is mounted to the circuit board 20, and the circuit board 20 is electrically connected to the power module 10 to control the power module 10. The converter 1 in this embodiment includes but is not limited to a converter with the power module 10, such as a direct current-to-alternating current converter and a direct current-to-direct current converter. Integration and electrical performance of the converter 1 with the power module 10 provided in this application are effectively improved.

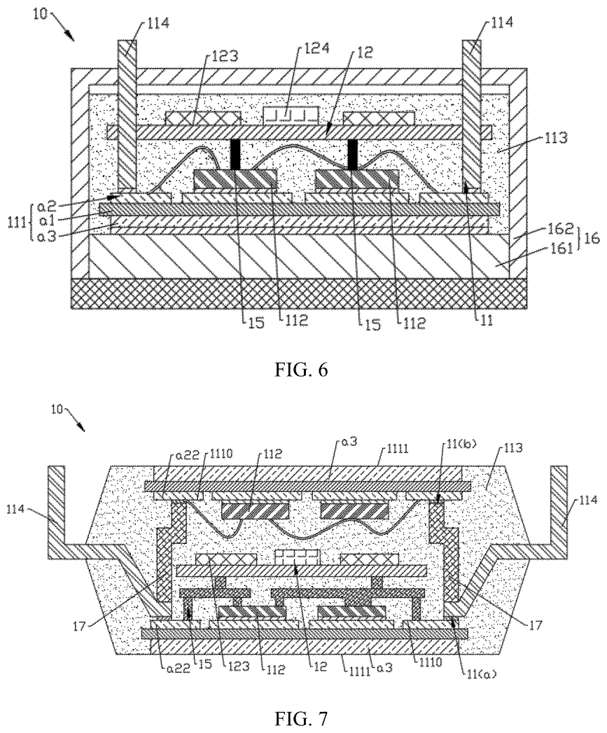

FIG. 3 is a schematic diagram of a structure of a first embodiment of the power module 10 of the converter 1 shown in FIG. 2.

The power module 10 includes a power assembly 11 and a drive board 12. The power assembly 11 includes a substrate 111, a power chip 112, and a package body 113. The power chip 112 is disposed on a mounting surface 1110 of the substrate 111. The package body 113 packages the power chip 112 on the substrate 111. The drive board 12 is disposed in the package body 113 and is located on a side, of the power chip 112, that backs the mounting surface 1110, to form a packaged structure 13 with the power assembly 11. The drive board 12 is electrically connected to the power chip 112, to drive the power chip 112 to operate. It may be understood that the package body 113 packages the drive board 12 and the power chip 112 on the substrate 111, to form the packaged structure 13.

In the power module 10 in this embodiment, the drive board 12 is disposed in the package body 113 of the power assembly 11, and the drive board 12 is located on the side, of the power chip 112, that backs the mounting surface 1110, to reduce a distance between the drive board 12 and the power chip 112. Further, a connection line between the power chip 112 and the drive board 12 is shortened, thereby effectively reducing a parasitic parameter of the connection line between the power chip 112 and the drive board 12, that is, reducing a parasitic parameter of the power module 10, and improving electrical performance of the power module 10. In addition, the drive board 12 is disposed in the package body 113 of the power assembly 11, that is, the drive board 12 is disposed inside the power assembly 11. Compared with disposing the drive board 12 and the power assembly 11 on a same plane, this can effectively reduce a planar area of the power module 10. When the package body 113 is formed for the power assembly 11, to ensure strength of the power assembly 11, a thickness of the power assembly 11 is usually greater than 5 mm. This thickness is sufficient to allow the drive board 12 to be embedded in the package body 113 of the power assembly 11, without increasing the thickness of the power assembly 11. That is, disposing the drive board 12 in the package body 113 does not affect the thickness of the power assembly 11, thereby effectively improving integration of the power module 10, reducing a package size and reducing costs of the power module 10.

It may be understood that there are mainly two parasitic parameters: a parasitic inductance and a parasitic resistance. A magnitude of the parasitic inductance is mainly affected by two factors: a length of the connection line, where a longer connection line results in a larger parasitic inductance; and an area surrounded by the connection line, where a larger area surrounded by the connection line results in a larger parasitic inductance. For the parasitic resistance, a longer connection line results in a larger parasitic resistance. Therefore, in this application, a shorter distance between the drive board 12 and the power chip 112 indicates a shorter connection line between the drive board 12 and the power chip 112, and an area surrounded by the connection line is also reduced, thereby effectively reducing a parasitic inductance and a parasitic resistance of the power module 10, and improving electrical performance of the power module 10.

The substrate 111 includes a bearing plate a1, a line layer a2, and a metal layer a3. The line layer a2 and the metal layer a3 are respectively formed on two opposite surfaces of the bearing plate a1, and the line layer a2 and the metal layer a3 are respectively located on two sides of the bearing plate a1, to ensure flatness of the bearing plate a1 and prevent warpage of the bearing plate a1. A surface, of the line layer a2, that backs the bearing plate a1 is the mounting surface 1110, that is, the power chip 112 is disposed on the surface, of the line layer a2, that backs the bearing plate a1. A surface, of the substrate 111, that backs the power chip 112 is a rear surface 1111, that is, a surface, of the metal layer a3, that backs the bearing plate a1 is the rear surface 1111, and the rear surface 1111 is exposed from the package body 113. The line layer a2 may be configured to implement an electrical connection between the power chip 112 and another device, or may be configured to implement an electrical connection between power chips 112. Because the rear surface 1111 of the metal layer a3 is exposed from the package body 113, the metal layer a3 can effectively transmit heat of the power chip 112 to the outside, thereby improving heat dissipation efficiency of the power chip 112. In addition, the metal layer a3 can further effectively enhance strength of the substrate 111.

In this embodiment, the bearing plate a1 may be made of an insulation and heat dissipation material such as ceramic. The ceramic may be, for example, a ceramic material such as aluminum oxide, silicon nitride, or aluminum nitride. The ceramic material has good heat dissipation effect, and can quickly dissipate heat for the power chip 112. The line layer a2 and the metal layer a3 are made of a metal material, for example, a copper, nickel, or aluminum material, and can quickly dissipate heat for the power chip 112. The line layer a2 and the metal layer a3 may be made of a same material or different materials. In addition, the line layer a2 is further configured to implement an electrical connection between the power chip 112 and another line. Certainly, in another embodiment, the bearing plate a1 may be alternatively made of another insulation material.

In this embodiment, the line layer a2 includes a first line a21 and a second line a22. Second lines a22 are located on two sides of the first line a21. Surfaces, of the first line a21 and the second line a22, that back the bearing plate a1 jointly constitute the mounting surface 1110. The power chip 112 is disposed on the first line a21, and the power chip 112 is connected to the second line a22 through a lead. Certainly, the power chip 112 may be alternatively connected to the second line a22 by using another conducting structure, and the second line a22 is connected to another element. That is, the second line a22 is configured to implement a connection between the power chip 112 and the another element. Certainly, in another embodiment, a structure of the line layer a2 is not limited to the foregoing descriptions, and a specific structure of the line layer a2 may be arranged according to a connection requirement of the power chip 112.

In this embodiment, there may be one or more power chips 112. In FIG. 3, for example, there are two power chips 112. The two power chips 112 are disposed on the first line a21 at a spacing, and the two power chips 112 are electrically connected through a lead. A lead connection process is mature and simple, and has low costs. The power chip 112 may be an insulated gate bipolar transistor (IGBT), a metal-oxide semiconductor field-effect transistor (MOSFET), and/or a diode. The power chip 112 may be fastened to the first line a21 through welding, bonding, or the like. For example, when the power chip 112 needs to be electrically connected to the first line a21, the power chip 112 may be fastened to the first line a21 through welding. When the power chip 112 does not need to be electrically connected to the first line a21, the power chip 112 may be fastened to the first line a21 in another manner such as bonding. Certainly, in another embodiment, the two power chips 112 may be alternatively connected by using a connection structure such as a lead frame.

The package body 113 in this embodiment is formed by using a plastic packaging process. The package body 113 may be made of, for example, a plastic material such as epoxy resin or silicone. The package body 113 formed by using the plastic packaging process has good sealing performance, so that moisture resistance and reliability of the packaged structure 13 can be improved. Specifically, the package body 113 is packaged in a region from the rear surface 1111 of the substrate 111 to a side, of the drive board 12, that backs the power chip 112, and no package body 113 is disposed at an edge of the side, of the drive board 12, that backs the power chip 112, thereby facilitating fitting between the power chip 112 and a related structure. In another embodiment, the package body 113 may be alternatively formed by using another process such as a housing packaging process.

The power assembly 11 further includes a pin 114. The pin 114 penetrates the drive board 12 and a part of the package body 113. One end of the pin 114 is disposed on the mounting surface 1110 and is electrically connected to the power chip 112, and the other end of the pin 114 is exposed from the package body 113. Specifically, the pin 114 is disposed on a second line a22 corresponding to the pin 114, so that the pin 114 is electrically connected, through the second line a22, to a power chip 112 corresponding to the pin 114. The pin 114 is configured to implement an electrical connection between the power chip 112 and the circuit board 20 (FIG. 2). Certainly, in another embodiment, the pin 114 of the power chip 112 may be alternatively configured to implement an electrical connection between the power chip 112 and the drive board 12. Alternatively, the pin 114 may not penetrate the drive board 12. Alternatively, the power chip 112 may be connected to the circuit board 20 by using a structure other than the pin 114.

In a direction perpendicular to the mounting surface 1110, a distance between the drive board 12 and the power chip 112 is less than a distance between the drive board 12 and a surface, of the package body 113, that backs the mounting surface 1110. In this embodiment, the distance between the drive board 12 and the power chip 112 is required to be less than the distance between the drive board 12 and the surface, of the package body 113, that backs the mounting surface 1110, to ensure that the distance between the drive board 12 and the power chip 112 is sufficiently short, thereby ensuring that the parasitic parameter of the connection line between the drive board 12 and the power chip 112 is sufficiently small, and effectively improving electrical performance of the power module 10.

In this embodiment, there are two pins 114, and the two pins 114 are respectively disposed on second lines a22 on two sides of the two power chips 112. In other words, the two power chips 112 are disposed between the two pins 114. The pin 114 may be welded to a second line a22 corresponding to the pin 114 by using solder paste, or may be fastened to a second line a22 corresponding to the pin 114 through ultrasonic welding, silver sintering, or the like. A shape of the pin 114 may be a cylindrical shape, an elliptic cylindrical shape, a cuboid shape, a polygonal shape, or the like. Shapes of the two pins 114 may be the same or different. A material of the pin 114 may be a metal or an alloy with good conductivity, for example, Cu, Ag, or Al. Certainly, in another embodiment, an arrangement manner of the power chip 112 and the pin 114 and a quantity of pins 114 may be alternatively arranged according to an actual requirement.

The drive board 12 includes a center region 121 and an edge region 122 surrounding the center region 121. The center region 121 is arranged opposite to the power assembly 11. Electronic elements such as a drive chip 123, a resistor 124, a capacitor, and an optocoupler are disposed in the center region 121 to form a drive circuit. The power chip 112 of the power assembly 11 is electrically connected to the drive chip 123. The packaged structure 13 includes a mounting hole 131. The mounting hole 131 is located in the edge region 122, and penetrates the drive board 12 and the package body 113 in a direction from the drive board 12 to the power chip 112. A related component is connected to the packaged structure 13 through the mounting hole. The edge region 122 and the package body 113 located in the edge region 122 may be understood as a mounting part of the packaged structure 13, so that the packaged structure 13 is fastened to another component by using the mounting part.

Certainly, in an implementation scenario of another embodiment, a related component may be alternatively fastened to the packaged structure 13 by using a screw or in another fastening manner. In another implementation scenario of another embodiment, the packaged structure 13 may be alternatively fastened to a related component in another connection manner such as bonding or clamping. In still another implementation scenario of another embodiment, small electronic elements such as the resistor 124, the capacitor, and the optocoupler may be alternatively partially disposed in the edge region 122. In yet another implementation scenario of another embodiment, when the drive board 12 does not need to be fastened to a related component, the drive board 12 may alternatively include only the center region 121, that is, the drive board 12 may not include the edge region 122.

In this embodiment, a surface, of the edge region 122, that backs the power chip 112 is exposed from the package body 113, that is, no package body 113 is disposed on the surface, of the edge region 122, that backs the power chip 112, so that a screw 132 is fastened through the surface, of the edge region 122, that backs the power chip 112. In addition, the package body 113 is made of a brittle material, and the package body 113 is prone to breakage under large stress. Because no package body 113 is disposed in the edge region 122, the screw 132 directly transmits a locking force to the drive board 12, thereby reducing the stress applied to the package body 113, and avoiding a risk that the package body 113 cracks because the screw 132 directly transmits the locking force to the package body 113.

The drive board 12 further includes a through hole 125. The through hole 125 is configured to allow a pin 114 corresponding to the drive board 12 to pass through, so that the pin 114 penetrates the drive board 12 and is connected to a related external element. In this embodiment, the pin 114 passes through the through hole 125 and is not electrically connected to the through hole 125. Certainly, in another embodiment, the pin 114 may be alternatively electrically connected to the drive board 12 through the through hole 125, to implement an electrical connection between the drive board 12 and the power chip 112.

The power module 10 further includes a heat sink 14, and the heat sink 14 is fastened to the packaged structure 13 and is in contact with the rear surface 1111. Specifically, the screw 132 is connected to the heat sink 14 through the mounting hole 131, to fasten the heat sink 14 to the packaged structure 13. The rear surface 1111 of the substrate 111 is in direct contact with the heat sink 14, so that heat of the power chip 112 can be quickly transmitted to the heat sink 14 and then transmitted by the heat sink 14 to the outside, thereby effectively improving heat dissipation efficiency of the power chip 112.

The power module 10 further includes a conductor 15. The conductor 15 is located between the power chip 112 and the drive board 12. The power chip 112 is connected to the drive board 12 through the conductor 15. Specifically, the drive chip 123 on the drive board 12 is connected to the power chip 112 of the power assembly 11 through the conductor 15. Because the drive board 12 is disposed in the package body 113 of the power assembly 11, the distance between the drive board 12 and the power chip 112 is reduced. Further, the connection line (the conductor 15) connected between the drive board 12 and the power chip 112 is shortened, thereby effectively reducing the parasitic parameter of the connection line of the power module 10, and improving electrical performance of the power module 10.

The conductor 15 in this embodiment may be implemented in a plurality of manners. Details are described below.

In an implementation, as shown in FIG. 3, the conductor is a copper rod 15, and two ends of the copper rod 15 are respectively electrically connected to the power chip 112 and the drive board 12. Specifically, the two ends of the copper rod 15 are electrically connected to the power chip 112 and the drive chip 123 on the drive board 12. A quantity of copper rods 15 corresponds to a quantity of power chips 112, and one copper rod 15 corresponds to one power chip 112. A length of the copper rod 15 is equal to the distance between the drive board 12 and the power chip 112. It may be understood that a length direction of the copper rod 15 is a flow direction of a current in the copper rod 15, so that the length of the copper rod 15 is the shortest, thereby effectively reducing the parasitic parameter of the connection line of the power module 10, and improving electrical performance of the power module 10. Certainly, in another embodiment, the power chip 112 may be alternatively connected to the drive board 12 by using another conducting structure such as a lead.

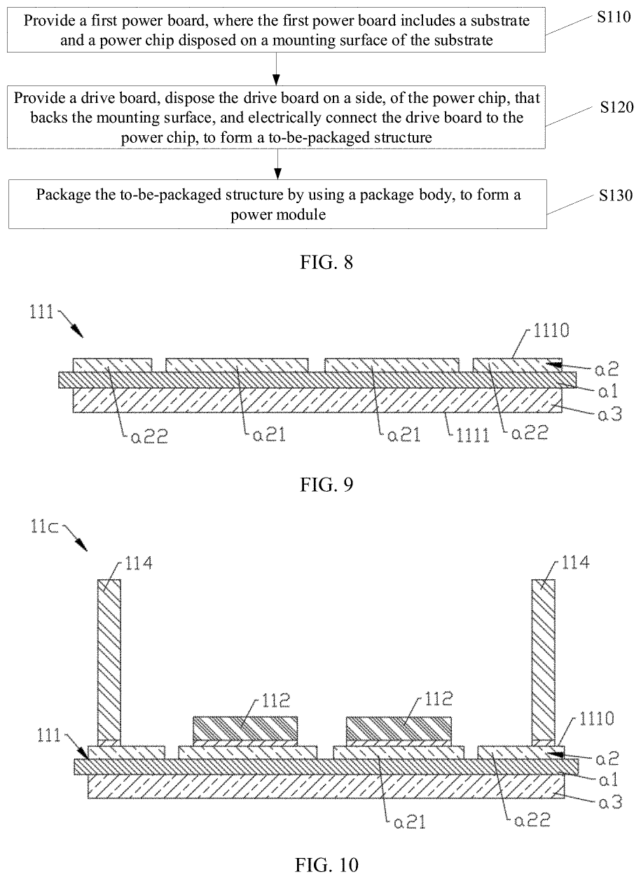

FIG. 4 is a schematic diagram of a structure of another implementation of the power module 10 shown in FIG. 3.

In another implementation, the conductor is a lead frame (LF) 15. The lead frame 15 includes a first terminal 151 and a second terminal 152 that are connected to each other. The first terminal 151 is electrically connected to the power chip 112. The second terminal 152 is electrically connected to the drive board 12. Specifically, the second terminal 152 is electrically connected to the drive chip 123 on the drive board 12. A quantity of lead frames 15 corresponds to a quantity of power chips 112. In this implementation, the lead frame 15 has a quite good through-current capability, thereby effectively reducing the parasitic parameter of the power module 10, and effectively improving a heat dissipation capability of the power chip 112. In addition, two power chips 112 may also be electrically connected through the lead frame, thereby effectively reducing manufacturing steps of the power module 10, and improving production efficiency of the power module 10.

The lead frame 15 further includes a third terminal 153 electrically connected to the first terminal 151, and the third terminal 153 is electrically connected to the pin 114. Specifically, the third terminal 153 is electrically connected to the second line a22, so as to be electrically connected to the pin 114. That is, the lead frame 15 in this implementation can also implement an electrical connection between the pin 114 and the power chip 112, so that no additional lead needs to be introduced to connect the power chip 112 and the pin 114. Therefore, a structure of the power module 10 is simpler, and manufacturing steps of the power module 10 are reduced, thereby improving production efficiency of the power module 10. In addition, compared with a lead, the lead frame 15 has a stronger through-current capability and a smaller parasitic parameter, so that heat dissipation effect of the power chip 112 can be further improved.

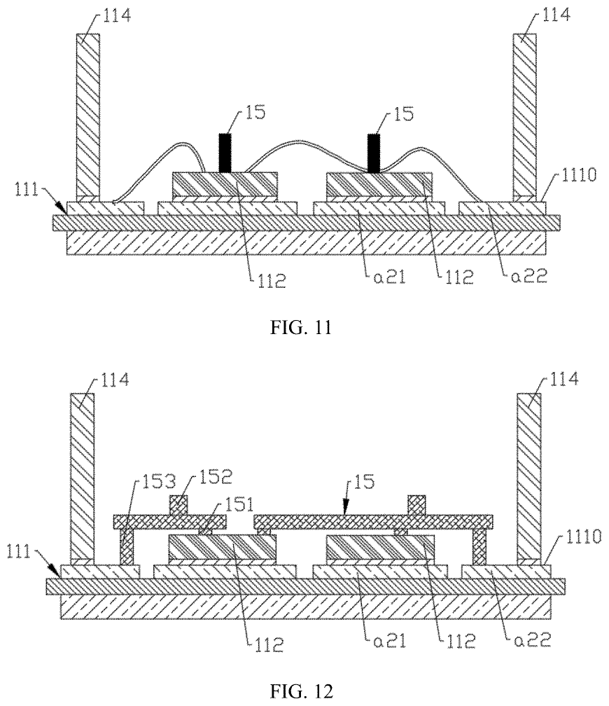

FIG. 5 is a schematic diagram of a structure of a second embodiment of the power module 10 shown in FIG. 2.

The structure of the power module 10 in this embodiment is approximately the same as that in the first embodiment. A difference lies in that, in this embodiment, the power chip 112 is electrically connected to the drive board 12 through the pin 114, and the pin 114 is electrically connected to the drive board 12, so that the drive board 12 is electrically connected to the power chip 112. Specifically, the pin 114 is electrically connected to a hole wall of the through hole 125 when penetrating the drive board 12 through the through hole 125, and the hole wall of the through hole 125 is electrically connected to the drive chip 123 on the drive board 12. An end, of the pin 114, that is away from the mounting surface 1110 is further connected to the circuit board 20 (FIG. 2). That is, the pin 114 can implement an electrical connection between the power chip 112 and the drive chip 123 on the drive board 12, and can also implement an electrical connection between the power chip 112 and the external circuit board 20, thereby simplifying a structure of the power module 10. Certainly, in another embodiment, the pin 114 may be alternatively configured to implement only an electrical connection between the power chip 112 and the drive chip 123 on the drive board 12.

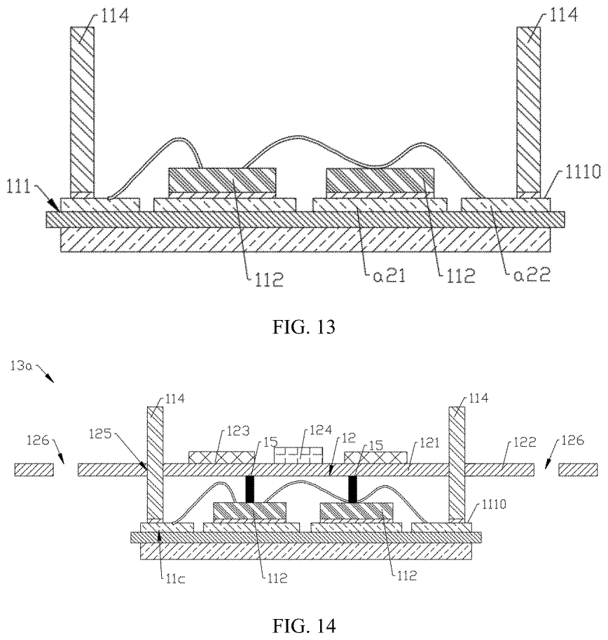

FIG. 6 is a schematic diagram of a structure of a third embodiment of the power module 10 shown in FIG. 2.

The structure of the power module 10 in this embodiment is approximately the same as that in the first embodiment. A difference lies in that, in this embodiment, the power module 10 further includes a package housing 16. The power assembly 11 and the drive board 12 are accommodated in the package housing 16. An end, of the pin 114, that backs the power chip 112 extends out of the package housing 16. The package body 113 is injected into a gap in the package housing 16 by using a housing packaging process. Specifically, a packaging material such as silicon gel or epoxy resin is injected into the package housing 16 to form the package body 113. In this application, the package body 113 is formed by using the housing packaging process. The process is simple, thereby effectively improving production efficiency of the power module 10.

The package housing 16 includes a base plate 161 and a cover 162. The cover 162 covers the base plate 161, and forms a space for accommodating the power assembly 11 and the drive board 12 with the base plate 161. Specifically, the metal layer a3 of the substrate 111 is fastened to the base plate 161 through welding, and an end, of the pin 114, that backs the power chip 112 extends out of the cover 162. In this embodiment, the metal layer a3 is fastened to the base plate 161 through welding. While ensuring strength of the connection between the substrate 111 and the base plate 161, this helps quickly transmit, to the base plate 161, heat transmitted from the power chip 112 to the substrate 111, so that the heat is transmitted to the outside through the base plate 161, thereby effectively improving heat dissipation efficiency of the power module 10. Certainly, the metal layer a3 of the substrate 111 may be alternatively fastened to the base plate 161 in another connection manner such as bonding or clamping.

In this embodiment, a lead is used to connect the two power chips 112 and connect the power chip 112 to the pin 114, and the power chip 112 is connected to the drive board 12 through the copper rod 15. Certainly, the power chip 112 may be alternatively connected to the drive board 12 through the lead. In addition, a lead frame 15 may be used to connect the two power chips 112, connect the power chip 112 to the pin 114, and connect the power chip 112 to the drive board 12.

The drive board 12 in this embodiment includes only a center region 121. Electronic elements such as a drive chip 123, a resistor 124, a capacitor, and an optocoupler are disposed in the center region 121 to form a drive circuit. The power chip 112 of the power assembly 11 is electrically connected to the drive chip 123.

The heat sink 14 is fastened to the base plate 161, and is in contact with a surface, of the base plate 161, that backs the substrate 111, so that the base plate 161 quickly transmits heat of the power chip 112 to the outside through the heat sink 14, thereby improving heat dissipation efficiency of the power chip 112, and further improving electrical performance of the power module 10. Specifically, the heat sink 14 may be fastened to the base plate 161 in one of connection manners such as screwing, clamping, and bonding. Certainly, in another embodiment, the power module in this embodiment may be alternatively not provided with a heat sink.

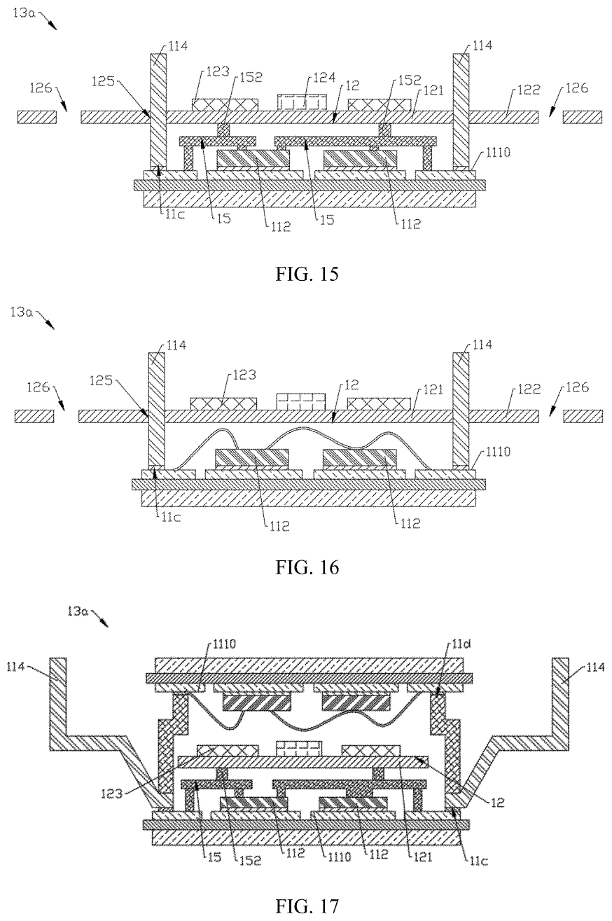

FIG. 7 is a schematic diagram of a structure of a fourth embodiment of the power module 10 shown in FIG. 2.

The structure of the power module 10 in this embodiment is approximately the same as that in the first embodiment. A difference lies in that there are two power assemblies 11 in this embodiment. Mounting surfaces 1110 of the two power assemblies 11 are arranged opposite to each other and are electrically connected to each other. Package bodies 113 of the two power assemblies 11 are connected. The drive board 12 is disposed between the two power assemblies 11 and is electrically connected to at least one power assembly 11. It may be understood that the drive board 12 may be embedded in a package body 113 of any one of the power assemblies 11; or the drive board 12 may be embedded between the package bodies 113 of the two power assemblies 11, to be specific, a part of the drive board 12 is embedded in a package body 113 of one power assembly 11, and the other part is embedded in a package body 113 of the other power assembly 11.

In this embodiment, the drive board 12 is embedded between the two power assemblies 11, to shorten distances between the drive board 12 and power chips 112 of the two power assemblies 11, and further shorten connection lines between the drive board 12 and the power chips 112 of the two power assemblies 11, thereby effectively reducing parasitic parameters of the connection lines, and improving electrical performance of the power module 10. In addition, surfaces, of metal layers a3 of the two power assemblies 11, that back the drive board 12 are both exposed from the package body 113, to dissipate heat for the power chips 112 corresponding to the two power assemblies 11, thereby improving heat dissipation efficiency of the power chips 112, and effectively improving electrical performance of the power module 10.

In this embodiment, as shown in FIG. 7, for ease of differentiation, the two power assemblies 11 are a power assembly 11a and a power assembly 11b, and the power assembly 11a is electrically connected to the drive board 12. Specifically, a power chip 112 of the power assembly 11a is connected to the drive chip 123 on the drive board 12 through the lead frame 15. Certainly, the power chip 112 of the power assembly 11a may be alternatively connected to the drive chip 123 on the drive board 12 by using a conducting structure such as a lead or a metal rod. In another embodiment, the drive board 12 may be alternatively electrically connected to the power chips 112 of the two power assemblies 11. In addition, the drive board 12 may be connected to the power assembly 11a and the power assembly 11b in a same manner or different manners.

The power module 10 includes a conducting rod 17 and a pin 114. Two ends of the conducting rod 17 are respectively connected to a mounting surface 1110 of the power assembly 11a corresponding to the conducting rod 17 and a mounting surface 1110 of the power assembly 11b corresponding to the conducting rod 17. Specifically, the two ends of the conducting rod 17 are respectively connected to a second line a22 of the power assembly 11a corresponding to the conducting rod 17 and a second line a22 of the power assembly 11b corresponding to the conducting rod 17, and are respectively electrically connected to the power chip 112 of the power assembly 11a and the power chip 112 of the power assembly 11b. One end of the pin 114 is fastened to the conducting rod 17 of the second line a22 of the power assembly 11a, and the other end of the pin 114 extends out of a side of a package body 113 of the power assembly 11a and/or a package body 113 of the power assembly 11b, to connect to a related external device, for example, a circuit board. As shown in FIG. 7, there are two conducting rods 17 and two pins 114, the two conducting rods 17 are respectively located on two sides of the two power chips 112, and the two pins 114 respectively extend out of the package body 113 from two sides of the package body 113. In this application, the conducting rod 17 is configured to implement an electrical connection between the power assembly 11a and the power assembly 11b, and the pin 114 is configured to connect the power assembly 11a and the power assembly 11b to an external device. Certainly, in another embodiment, quantities and specific structures of pins 114 and conducting rods 17 are not limited to the foregoing descriptions.

In this embodiment, the lead frame 15 is used to connect two power chips 112 of the power assembly 11a, and connect the power chips 112 to the conducting rods 17. A lead is used to connect two power chips 112 of the power assembly 11b, and connect the power chips 112 to the conducting rods 17. Certainly, a lead or another conducting structure may be alternatively used to connect the two power chips 112 of the power assembly 11a, and connect the power chips 112 to the conducting rods 17. The lead frame 15 or another conducting structure may be alternatively used to connect the two power chips 112 of the power assembly 11b, and connect the power chips 112 to the conducting rods 17.

The package body 113 of the power assembly 11a and the package body 113 of the power assembly 11b are integrated, so that connection strength of the packaged structure 13 including the power assembly 11a, the power assembly 11b, and the drive board 12 is higher. Specifically, the package body 113 of the power assembly 11a and the package body 113 of the power assembly 11b form an integrally molded package body 113 by using a plastic packaging process. Certainly, the package body 113 of the power assembly 11a and the package body 113 of the power assembly 11b may be alternatively formed by using a housing packaging process.

The protection scope of this application is not limited to the first embodiment to the fourth embodiment, and any combination of the first embodiment to the fourth embodiment also falls within the protection scope of this application. That is, the foregoing plurality of embodiments may be alternatively combined according to an actual requirement.

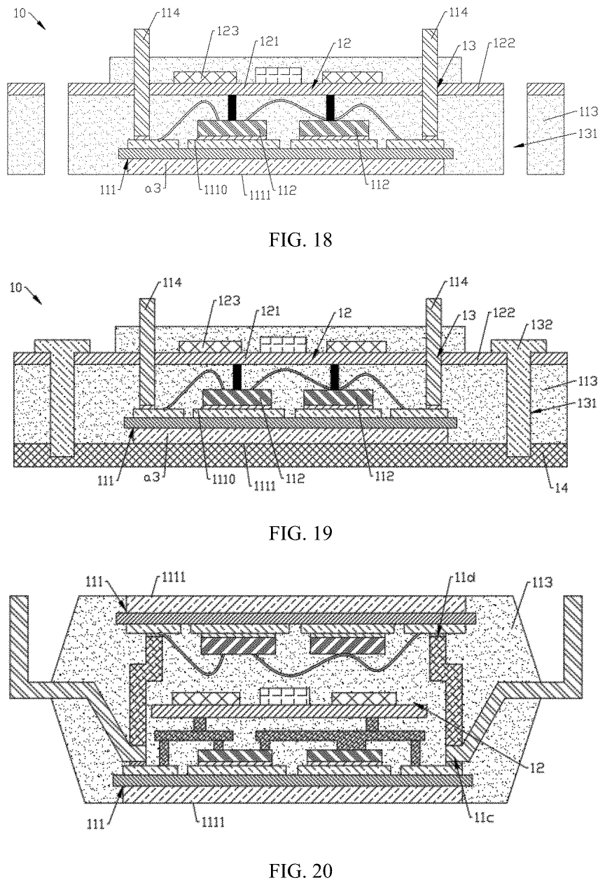

FIG. 8 is a schematic flowchart of a manufacturing method for the power module shown in FIG. 3. As shown in FIG. 8, the manufacturing method for the power module includes operations S110 to S130.

Operation S110: Provide a first power board, where the first power board includes a substrate 111 and a power chip 112 disposed on a mounting surface 1110 of the substrate 111.

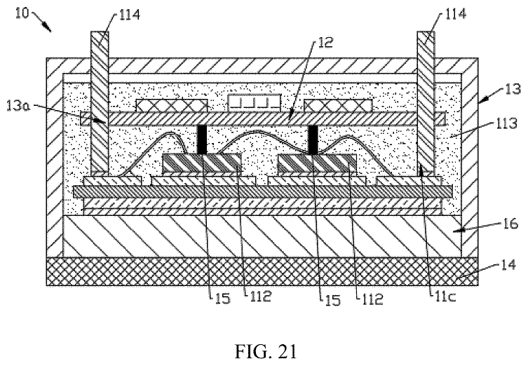

Specifically, as shown in FIG. 9 to FIG. 12, specific steps of providing the first power board 11c are as follows: First, as shown in FIG. 9, the substrate 111 is provided. The substrate 111 includes a bearing plate a1, a line layer a2, and a metal layer a3. The line layer a2 and the metal layer a3 are respectively formed on two opposite surfaces of the bearing plate a1, and the line layer a2 and the metal layer a3 are respectively located on two sides of the bearing plate a1, to ensure flatness of the bearing plate a1 and prevent warpage of the bearing plate a1. A surface, of the line layer a2, that backs the bearing plate a1 is the mounting surface 1110, that is, the power chip is disposed on the surface, of the line layer a2, that backs the bearing plate a1. A surface, of the substrate 111, that backs the power chip is a rear surface 1111, that is, a surface, of the metal layer a3, that backs the bearing plate a1 is the rear surface 1111. The line layer a2 includes a first line a21 and a second line a22. Second lines a22 are located on two sides of the first line a21. Surfaces, of the first line a21 and the second line a22, that back the bearing plate a1 jointly constitute the mounting surface 1110. Certainly, in another embodiment, a structure of the line layer a2 is not limited to the foregoing structure, and a specific structure of the line layer a2 may be arranged according to a connection requirement of the power chip.

In this embodiment, the bearing plate a1 may be made of an insulation and heat dissipation material such as ceramic. The ceramic may be, for example, a ceramic material such as aluminum oxide, silicon nitride, or aluminum nitride. The ceramic material has good heat dissipation effect, and can quickly dissipate heat for the power chip disposed on the substrate 111 in a subsequent process. The line layer a2 and the metal layer a3 are made of a metal material, for example, a copper, nickel, or aluminum material, can quickly dissipate heat for the power chip disposed on the substrate 111 in the subsequent process, and can further effectively enhance strength of the substrate 111. The line layer a2 and the metal layer a3 may be made of a same material or different materials. In addition, the line layer a2 is further configured to implement an electrical connection between the power chip disposed on the substrate 111 in the subsequent process and another line. Certainly, in another embodiment, the bearing plate a1 may be alternatively made of another insulation material.

Then, as shown in FIG. 10, the power chip 112 is provided. The power chip 112 may be an insulated gate bipolar transistor (IGBT), a metal-oxide semiconductor field-effect transistor (MOSFET), and/or a diode. Certainly, in another embodiment, the power chip 112 may be provided before the substrate 111 Alternatively, the substrate 111 and the power chip 112 may be provided simultaneously.

Then the power chip 112 is disposed on the mounting surface 1110 of the substrate 111. Specifically, soldering tin is printed on the first line a21, and then the power chip 112 is welded to the first line a21. In this embodiment, there are two power chips 112. The two power chips 112 are disposed on the first line a21 at a spacing. Certainly, in another embodiment, one or more power chips 112 may be alternatively welded to the first line a21. Alternatively, the power chip 112 may be fastened to the first line a21 through welding, bonding, or the like based on different conditions. For example, when the power chip 112 needs to be electrically connected to the first line a21, the power chip 112 may be fastened to the first line a21 through welding. When the power chip 112 does not need to be electrically connected to the first line a21, the power chip 112 may be fastened to the first line a21 in another manner such as bonding.

When the power chip 112 is disposed on the mounting surface 1110 of the substrate 111, a pin 114 is fastened to the mounting surface 1110. First, soldering tin is printed on both the first line a21 and the second line a22. Then the power chip 112 is welded to the first line a21, and the pin 114 is welded to the second line a22 at the same time. Specifically, there are two pins 114, and the two pins 114 are respectively welded to second lines a22 on two sides of the two power chips 112. In this embodiment, the pin 114 is perpendicular to the mounting surface 1110. Alternatively, the pin 114 may be fastened to a second line a22 corresponding to the pin 114 through welding by using solder paste, ultrasonic welding, silver sintering, or the like. A shape of the pin 114 may be a cylindrical shape, an elliptic cylindrical shape, a cuboid shape, a polygonal shape, or the like. Shapes of the two pins 114 may be the same or different. A material of the pin 114 may be a metal or an alloy with good conductivity, for example, Cu, Ag, or Al. Certainly, a quantity and an arrangement manner of pins 114 may be alternatively arranged according to an actual requirement. Alternatively, the pin 114 may not be perpendicular to the mounting surface 1110.

In this embodiment, the power chip 112 and the pin 114 are simultaneously mounted to the mounting surface 1110. This helps reduce manufacturing steps of the power module, reduce production costs, and improve production efficiency of the power module. In another embodiment, alternatively, the power chip 112 may be mounted to the mounting surface 1110 before the pin 114, or the pin 114 may be mounted to the mounting surface 1110 before the power chip 112.

Then, as shown in FIG. 11 and FIG. 12, a conductor 15 electrically connected to the power chip 112 is formed on a surface, of the power chip 112, that backs the mounting surface 1110, and the conductor 15 is configured to electrically connect the power chip 112 to a related element mounted in a subsequent process. Specifically, steps of forming the conductor 15 may be implemented in a plurality of manners. Details are described as follows.

In an implementation, as shown in FIG. 11, when the conductor is a copper rod 15, before the conductor 15 is formed on the surface, of the power chip 112, that backs the mounting surface 1110, first, the two power chips 112 are electrically connected, and the power chip 112 is electrically connected to a pin 114 corresponding to the power chip 112. The two power chips 112 are connected through a lead, and the power chip 112 is indirectly electrically connected to the pin 114 corresponding to the power chip 112. Specifically, the lead is connected between the second line a22 and the power chip 112, so that the power chip 112 is indirectly electrically connected to the pin 114 corresponding to the power chip 112. A lead connection process is mature and simple, and has low costs. Certainly, in another embodiment, a connection structure such as a lead frame may be alternatively used to connect the two power chips 112, and connect the power chip 112 to the pin 114 corresponding to the power chip 112. Then one end of the copper rod 15 is fastened to the surface, of the power chip 112, that backs the mounting surface 1110, and is electrically connected to the power chip 112. A quantity of copper rods 15 corresponds to a quantity of power chips 112, and one copper rod 15 corresponds to one power chip 112. Certainly, in another embodiment, the conductor 15 may be alternatively connected by using another conducting structure such as a lead.

In another implementation, as shown in FIG. 12, when the conductor is a lead frame 15, the lead frame 15 is provided. The lead frame 15 includes a first terminal 151, a second terminal 152, and a third terminal 153 that are connected to each other, and the first terminal 151 is electrically connected to the second terminal 152 and the third terminal 153. In this embodiment, there are two lead frames 15. The first terminal 151 of the lead frame 15 is electrically connected to a power chip 112 corresponding to the lead frame 15, and the third terminal 153 is connected to a second line a22 corresponding to the lead frame 15, so that the lead frame 15 is connected to a pin 114 corresponding to the lead frame 15 through the second line a22. The second terminal 152 is configured to connect to a related element in a subsequent process. In addition, the two power chips 112 can be further electrically connected through the lead frame 15.

When the conductor is the lead frame 15, the lead frame 15 implements both an electrical connection between the pin 114 and the power chip 112 and an electrical connection between the two power chips 112, so that no additional lead needs to be introduced to connect the power chip 112 and the pin 114 and connect the two power chips 112. Therefore, a structure of the power module is simpler, and manufacturing steps of the power module are reduced, thereby improving production efficiency of the power module. In addition, compared with a lead, the lead frame 15 has a stronger through-current capability and a smaller parasitic parameter, so that heat dissipation effect of the power chip 112 can be further improved.

Certainly, in another embodiment, as shown in FIG. 13, no conductor needs to be formed on the surface, of the power chip 112, that backs the mounting surface 1110, and a lead is used to directly connect the power chip 112 to the pin 114, and connect the two power chips 112. Alternatively, another conducting structure is used to directly connect the power chip 112 to the pin 114, and connect the two power chips 112.

Operation S120: Provide a drive board 12, dispose the drive board 12 on a side, of the power chip 112, that backs the mounting surface 1110, and electrically connect the drive board 12 to the power chip 112, to form a to-be-packaged structure 13a.

Specifically, as shown in FIG. 14 to FIG. 16, first, the drive board 12 is provided. In this embodiment, as shown in FIG. 14, the drive board 12 includes a center region 121 and an edge region 122 surrounding the center region 121. Electronic elements such as a drive chip 123, a resistor 124, a capacitor, and an optocoupler are disposed in the center region 121 to form a drive circuit. The drive board 12 further includes a through hole 125 and a via 126. The through hole 125 is located in the center region 121, and the via 126 is located in the edge region 122. Certainly, in another embodiment, small electronic elements such as the resistor 124, the capacitor, and the optocoupler may be alternatively partially disposed in the edge region 122. Alternatively, the drive board 12 may include only the center region 121, that is, the drive board 12 may not include the edge region 122.

Then the drive board 12 is disposed on the side, of the power chip 112, that backs the mounting surface 1110, and the drive board 12 is electrically connected to the power chip 112, to form the to-be-packaged structure 13a. Specifically, the drive board 12 is disposed between two ends of the pin 114, and is close to an end, of the pin 114, that is electrically connected to the power chip 112. The drive board 12 is required to be disposed close to the end, of the pin 114, that is electrically connected to the power chip 112, to ensure that a distance between the drive board 12 and the power chip 112 is sufficiently short, thereby ensuring that a parasitic parameter of a connection line between the drive board 12 and the power chip 112 is sufficiently small, and effectively improving electrical performance of the power module.

Specifically, this step may be implemented in a plurality of manners. In an implementation, in a scenario in which the copper rod 15 or the lead frame 15 is disposed on the surface, of the power chip 112, that backs the mounting surface 1110, as shown in FIG. 14 and FIG. 15, first, the drive board 12 is disposed at an end, of the copper rod 15, that backs the power chip 112 or is disposed at the second terminal 152 of the lead frame 15, the center region 121 is arranged opposite to the first power board 11c, and the pin 114 passes through the through hole 125 on the drive board 12 and is connected to the drive board 12 in an insulated manner. Then the end, of the copper rod 15, that backs the power chip 112 or the second terminal 152 of the lead frame 15 is welded to the drive board 12, so that the drive chip 123 on the drive board 12 is electrically connected to the power chip 112 through the conductor 15, to form the to-be-packaged structure 13a.

In this implementation, a length of the copper rod 15 is equal to the distance between the drive board 12 and the power chip 112. It may be understood that a length direction of the copper rod 15 is a flow direction of a current in the copper rod 15, so that the length of the copper rod 15 is the shortest, that is, the connection line between the drive board 12 and the power chip 112 is the shortest, thereby effectively reducing the parasitic parameter of the connection line of the power module, and improving electrical performance of the power module.

In another implementation, in a scenario in which no copper rod 15 or lead frame 15 is disposed on the surface, of the power chip 112, that backs the mounting surface 1110, as shown in FIG. 16, first, the drive board 12 is disposed on a side, of the power chip 112, that backs the mounting surface 1110, the center region 121 is arranged opposite to the first power board 11c, and the pin 114 passes through the through hole 125 on the drive board 12. Then a hole wall of the through hole 125 is electrically connected to the pin 114, so that the drive chip 123 on the drive board 12 is electrically connected to the power chip 112 through the pin 114, to form the to-be-packaged structure 13a.

In another embodiment, the drive board 12 includes only the center region 121, a copper rod or a lead frame is disposed on the surface, of the power chip 112, that backs the mounting surface 1110, and the pin 114 is not perpendicular to the mounting surface 1110. In this scenario, as shown in FIG. 17, an example in which the lead frame 15 is disposed on the surface, of the power chip 112, that backs the mounting surface 1110 is used for description in FIG. 17. First, the drive board 12 is disposed at the second terminal 152 of the lead frame 15, and the center region 121 is arranged opposite to the first power board 11c and is located between two pins 114. Then the second terminal 152 of the lead frame 15 is welded to the drive board 12, so that the drive chip 123 on the drive board 12 is electrically connected to the power chip 112 through the lead frame 15. Finally, a second power board 11d is provided. Structures of the second power board 11d and the first power board 11c are basically the same. The second power board 11d is disposed on a side, of the drive board 12, that backs the first power board 11c, and is electrically connected to the first power board 11c, to form the to-be-packaged structure 13a. Specifically, a mounting surface 1110 of the second power board 11d is arranged opposite to the mounting surface 1110 of the first power board 11c. That is, the first power board 11c and the second power board 11d are symmetrically disposed on two sides of the drive board 12. Certainly, an arrangement manner of the pin 114, the drive board 12, the first power board, and the second power board is not limited to the foregoing descriptions. Alternatively, the power chip 112 may be connected to a circuit board by using a structure other than the pin 114.

Operation S130: Package the to-be-packaged structure 13a by using a package body 113, to form a power module.

Specifically, as shown in FIG. 18 and FIG. 19, in this embodiment, the to-be-packaged structure 13a is packaged by using a plastic packaging process. The to-be-packaged structure 13a may be the to-be-packaged structure 13a shown in FIG. 14, FIG. 15, FIG. 16, and FIG. 17. An example in which the to-be-packaged structure 13a is the to-be-packaged structure 13a shown in FIG. 14 is used below for description. Specifically, first, the to-be-packaged structure 13a is placed in a package mold. An end, of the pin 114, that is away from the power chip 112 extends out of the package mold. An avoidance structure is disposed in the package mold, and the avoidance structure is located on a surface, of the edge region 122 of the drive board 12, that backs the power chip 112, and extends, through the via in the edge region 122, toward a plane on which the rear surface 1111 of the substrate 111 is located. Then the package mold is filled with the package body 113. The package body 113 may be made of, for example, a plastic material such as epoxy resin. After being cured, the package body 113 forms the packaged structure 13 with the to-be-packaged structure 13a, so as to form the power module 10. Finally, the package mold is removed. In this embodiment, the power module 10 formed by using the plastic packaging process has good sealing performance, so that moisture resistance and reliability of the power module 10 can be improved.

In this embodiment, the package body 113 is packaged in a region from the rear surface 1111 of the substrate 111 to the side, of the drive board 12, that backs the power chip 112, and the end, of the pin 114, that is away from the power chip 112 is exposed from the package body 113, to be electrically connected to a related external device. The rear surface 1111 of the substrate 111 is exposed from the package body 113. Because the rear surface 1111 of the metal layer a3 is exposed from the package body 113, the metal layer a3 can effectively transmit heat of the power chip 112 to the outside, thereby improving heat dissipation efficiency of the power chip 112. In addition, the formed packaged structure 13 includes the via 126 formed by the avoidance structure avoiding the package body 113 and a mounting hole 131 of the package body 113, and a related component is connected to the packaged structure 13 through the mounting hole 131. A surface, of the edge region 122, that backs the power chip 112 is exposed from the package body 113, thereby facilitating fitting between the power chip 112 and a related structure.

In a direction perpendicular to the mounting surface 1110, a distance between the drive board 12 and the power chip 112 is less than a distance between the drive board 12 and a surface, of the package body 113, that backs the mounting surface 1110. In this embodiment, the distance between the drive board 12 and the power chip 112 is required to be less than the distance between the drive board 12 and the surface, of the package body 113, that backs the mounting surface 1110, to ensure that the distance between the drive board 12 and the power chip 112 is sufficiently short, thereby ensuring that the parasitic parameter of the connection line between the drive board 12 and the power chip 112 is sufficiently small, and effectively improving electrical performance of the power module 10.

Finally, as shown in FIG. 19, a heat sink 14 is fastened to the packaged structure 13, and the heat sink 14 is in contact with the rear surface 1111 of the substrate 111, to improve heat dissipation efficiency of the power chip 112. A specific step of fastening the heat sink 14 to the packaged structure 13 is as follows: A screw 132 passes through the mounting hole 131 from the surface, of the edge region 122, that backs the power chip 112, and is tightened to the heat sink 14. No package body 113 is disposed on the surface, of the edge region 122, that backs the power chip 112, so that the screw 132 is fastened through the surface, of the edge region 122, that backs the power chip 112. In addition, the package body 113 is made of a brittle material, and the package body 113 is prone to breakage under large stress. Because no package body is disposed in the edge region 122, the screw 132 directly transmits a locking force to the drive board 12, thereby reducing the stress applied to the package body 113, and avoiding a risk that the package body 113 cracks because the screw 132 directly transmits the locking force to the package body 113. Certainly, in another embodiment, the heat sink 14 may be alternatively fastened to the packaged structure 13 by using a screw or in another fastening manner. Alternatively, the packaged structure 13 may be alternatively fastened to the heat sink 14 in another connection manner such as bonding or clamping.

As shown in FIG. 20, in an embodiment in which the to-be-packaged structure 13a (FIG. 17) includes a first power board 11c, a drive board 12, and a second power board 11d, after the to-be-packaged structure 13a is packaged by using the package body 113, rear surfaces 1111 of substrates 111 of the first power board 11c and the second power board 11d are both exposed from the package body 113, so that the substrates 111 of the first power board 11c and the second power board 11d are respectively connected to heat sinks corresponding to the rear surfaces 1111 of the substrates 111 of the first power board 11c and the second power board 11d, so as to implement good heat dissipation for the power module 10.

In another embodiment, as shown in FIG. 21, a specific method for packaging the to-be-packaged structure 13a by using the package body 113 may be alternatively as follows: First, a package housing 16 is provided, the to-be-packaged structure 13a is fastened in the package housing 16, and an end, of the pin 114, that is away from the mounting surface 1110 is exposed from the package housing 16. The to-be-packaged structure 13a may include a first power board 11c and a drive board 12 (as shown in FIG. 21), or may include a first power board 11c, a drive board 12, and a second power board. Then adhesive is injected into the package housing 16 to fill a gap in the package housing 16, so as to form the package body 113. The package body 113, the to-be-packaged structure 13a, and the package housing 16 jointly constitute the packaged structure 13, to form the power module 10. Specifically, silicon gel is injected into the package housing 16 to form the package body 113. In this embodiment, the package body 113 is formed by using a housing packaging process. The process is simple, thereby effectively improving production efficiency of the power module 10. In a scenario of this embodiment, the drive board 12 in the to-be-packaged structure 13a includes only a center region 121. The heat sink 14 is disposed on the package housing 16 to dissipate heat for the power module 10.

In the manufacturing method for the power module 10 in this application, the drive board 12 is disposed on the side, of the power chip 112, that backs the mounting surface 1110, the drive board 12 is electrically connected to the power chip 112 to form the to-be-packaged structure 13a, and then the to-be-packaged structure 13a is packaged to form the packaged structure 13. To be specific, the drive board 12 and the power chip 112 are packaged together, so that a distance between the drive board 12 and the power chip 112 can be shortened. Further, a connection line between the power chip 112 and the drive board 12 is shortened, thereby effectively reducing a parasitic parameter of the connection line between the power chip 112 and the drive board 12, that is, reducing a parasitic parameter of the power module 10, and improving electrical performance of the power module 10. In addition, the drive board 12 and the first power board 11c are packaged together. Compared with disposing the drive board 12 and the first power board 11c on a same plane, this can effectively reduce a planar area of the power module 10. During packaging of the first power board 11c, to ensure strength of the first power board 11c after packaging, a thickness of the first power board 11c after packaging is usually greater than 5 mm. This thickness is sufficient to allow the drive board 12 and the first power board 11c to be packaged together without increasing the thickness of the first power board 11c. That is, packaging the drive board 12 and the first power board 11c together does not affect the thickness obtained after packaging, thereby effectively improving integration of the power module 10, reducing a package size, and reducing costs of the power module 10.

The foregoing descriptions are merely specific implementations of this application, but are not intended to limit the protection scope of this application. Any variation or replacement readily figured out by a person skilled in the art within the technical scope disclosed in this application shall fall within the protection scope of this application. Therefore, the protection scope of this application shall be subject to the protection scope of the claims.

What is claimed is:

1. A power module, wherein the power module comprises a power assembly and a drive board, the power assembly comprises a substrate, a power chip, and a package body, the power chip is disposed on a mounting surface of the substrate, the package body packages the power chip on the substrate, the drive board is disposed in the package body and is located on a side of the power chip that backs the mounting surface, and the drive board is electrically connected to the power chip.

2. The power module according to claim 1, wherein in a direction perpendicular to the mounting surface, a distance between the drive board and the power chip is less than a distance between the drive board and a surface of the package body that backs the mounting surface.

3. The power module according to claim 1 wherein the power assembly further comprises a pin, the pin penetrates the drive board and a part of the package body, one end of the pin is disposed on the mounting surface and is electrically connected to the power chip, and the other end of the pin is exposed from the package body.

4. The power module according to claim 3, wherein the drive board is electrically connected to the power chip through the pin.

5. The power module according to claim 3, wherein the power module further comprises a conductor, the conductor is located between the power chip and the drive board, and the power chip is connected to the drive board through the conductor.

6. The power module according to claim 5, wherein the conductor is a copper rod, and two ends of the copper rod are respectively electrically connected to the power chip and the drive board.

7. The power module according to claim 5, wherein the conductor is a lead frame, the lead frame comprises a first terminal and a second terminal that are connected to each other, the first terminal is electrically connected to the power chip, and the second terminal is electrically connected to the drive board.

8. The power module according to claim 7, wherein the lead frame further comprises a third terminal electrically connected to the first terminal, and the third terminal is electrically connected to the pin.

9. The power module according to claim 3, wherein the power module further comprises a package housing, the power assembly and the drive board are accommodated in the package housing, an end, of the pin, that backs the power chip extends out of the package housing, and the package body is injected into a gap in the package housing by using a housing packaging process.

10. The power module according to claim 1, wherein the drive board and the power assembly constitute a packaged structure, a surface of the substrate that backs the power chip is a rear surface, the rear surface is exposed from the package body, the power module further comprises a heat sink, and the heat sink is fastened to the packaged structure and is in contact with the rear surface.

11. The power module according to claim 10, wherein the drive board comprises a center region and an edge region surrounding the center region, the center region is arranged opposite to the power assembly, the packaged structure comprises a mounting hole, the mounting hole is located in the edge region and penetrates the drive board and the package body in a direction from the drive board to the power chip, and the heat sink is connected to the packaged structure through the mounting hole.

12. The power module according to claim 11, wherein a surface of the edge region that backs the power chip is exposed from the package body, so that a screw is fastened through the surface of the edge region that backs the power chip.

13. The power module according to claim 1, wherein there are two power assemblies, mounting surfaces of the two power assemblies are arranged opposite to each other and are electrically connected to each other, package bodies of the two power assemblies are connected, and the drive board is disposed between the two power assemblies and is electrically connected to at least one power assembly.

14. A converter, wherein the converter comprises a circuit board and the power module according to claim 1, and the power module is electrically connected to the circuit board.

15. An electronic device, wherein the electronic device comprises the converter according to claim 14, and the converter is configured to convert an electrical signal of the electronic device.

16. A manufacturing method for a power module, wherein the manufacturing method comprises:
providing a first power board, wherein the first power board comprises a substrate and a power chip disposed on a mounting surface of the substrate;
providing a drive board, disposing the drive board on a side, of the power chip, that backs the mounting surface, and electrically connecting the drive board to the power chip, to form a to-be-packaged structure; and
packaging the to-be-packaged structure by using a package body, to form a power module.

17. The manufacturing method for a power module according to claim 16, wherein the manufacturing method further comprises: before the disposing the drive board on a side of the power chip that backs the mounting surface, forming, on a surface of the power chip that backs the mounting surface, a conductor electrically connected to the power chip, wherein when the drive board is disposed on the side of the power chip that backs the mounting surface, the drive board is electrically connected to the conductor.

18. The manufacturing method for a power module according to claim 17, wherein the conductor is a copper rod, or the conductor is a lead frame.

19. The manufacturing method for a power module according to claim 16, wherein the manufacturing method further comprises: when the power chip is disposed on the mounting surface of the substrate, fastening a pin to the mounting surface, wherein when the drive board is disposed on the side of the power chip that backs the mounting surface, the pin penetrates the drive board.

20. The manufacturing method for a power module according to claim 16, wherein the manufacturing method further comprises: after the drive board is electrically connected to the first power board, providing a second power board, disposing the second power board on a side of the drive board that backs the first power board, and electrically connecting the second power board to the first power board, to form a to-be-packaged structure.
